(19) United States
(12) Patent Application Publication
(10) Pub. No.: US 2025/0357212 A1
(43) Pub. Date: Nov. 20, 2025

(54) SEMICONDUCTOR WAFER INCLUDING FRAME IDENTIFIER, METHOD OF PROCESSING A SEMICONDUCTOR WAFER USING FRAME IDENTIFIER, AND SEMICONDUCTOR CHIP

(71) Applicant: SK hynix Inc., Icheon-si Gyeonggi-do (KR)

(72) Inventors: Min Gyu KANG, Icheon-si Gyeonggi-do (KR); Sung Kee PARK, Icheon-si Gyeonggi-do (KR); Ho Jun SON, Icheon-si Gyeonggi-do (KR); Jae Bum CHOI, Icheon-si Gyeonggi-do (KR)

(73) Assignee: SK hynix Inc., Icheon-si Gyeonggi-do (KR)

(21) Appl. No.: 18/944,328

(22) Filed: Nov. 12, 2024

(30) Foreign Application Priority Data
May 14, 2024 (KR) 10-2024-0063487

(51) Int. Cl. H01L 21/78; H01L 23/544

(52) U.S. Cl. CPC H01L 21/78; H01L 23/544; H01L 2223/5446

(57) ABSTRACT

A semiconductor chip according to an embodiment includes a substrate including a chip region and a residual scribe lane surrounding the chip region, and an infrared marker disposed inside the chip region or in the residual scribe lane. The infrared marker includes a plurality of optical patterns. The plurality of optical patterns includes integrated circuit structures with different stack structures over the substrate, and the plurality of optical patterns have differing infrared reflection characteristics.

### CROSS-REFERENCE TO RELATED APPLICATIONS

The present application claims priority under 35 U.S.C. § 119(a) to Korean patent Application No. 10-2024-0063487, filed in the Korean Intellectual Property Office on May 14, 2024, which application is incorporated herein by reference in its entirety.

### BACKGROUND

### 1. Technical Field

The present disclosure generally relates to semiconductor wafer manufacturing, including but not limited to dicing of semiconductor wafers.

### 2. Related Art

A plurality of semiconductor devices are formed on a semiconductor wafer through integrated circuit processes. The plurality of semiconductor devices formed on the semiconductor wafer are separated into individual semiconductor chips through wafer dicing.

Recently, as semiconductor integration increases, the thickness of the semiconductor wafer decreases, and the method of wafer dicing is also becoming more diverse. For example, wafer dicing may be classified into blade dicing, laser dicing, plasma dicing, and so forth.

### SUMMARY

A semiconductor chip according to an embodiment of the present disclosure includes a substrate including a chip region and a residual scribe lane surrounding the chip region, and an infrared marker disposed inside the chip region or in the residual scribe lane. The infrared marker includes a plurality of optical patterns. The plurality of optical patterns includes integrated circuit structures with different stack structures over the substrate, and the plurality of optical patterns have differing infrared reflection characteristics.

A semiconductor wafer according to an embodiment of the present disclosure includes a unit frame repeatedly arranged on a substrate. The unit frame includes a plurality of chip regions, a scribe lane disposed between the plurality of chip regions, and a frame identifier disposed in at least one of the plurality of chip regions or in the scribe lane. The frame identifier provides references that identify positions of a plurality of dicing lines.

A method of processing a semiconductor wafer according to an embodiment of the present disclosure may include forming a semiconductor wafer including unit frames repeatedly arranged on a substrate. At least one of the unit frames includes a frame identifier located in one or more of a plurality of chip regions or a scribe lane between the plurality of chip regions. The positions of a plurality of dicing lines in the scribe lane are determined using the frame identifier. The plurality of dicing lines are configured to separate the plurality of chip regions. The process conditions of a dicing process are determined for at least one position of the plurality of dicing lines. The semiconductor wafer is diced along the plurality of dicing lines based on the process conditions.

### BRIEF DESCRIPTION OF THE DRAWINGS

FIG. 1A to FIG. 1E illustrate perspective views of a wafer during a wafer processing process according to an embodiment of the present disclosure.

FIG. 2A to FIG. 2E illustrate cross-sectional views of a wafer during a wafer processing process according to an embodiment of the present disclosure.

FIG. 3 is a plan view illustrating a semiconductor wafer according to an embodiment of the present disclosure.

FIG. 4 is a view illustrating a unit frame and dicing lines of a semiconductor wafer according to an example of the present disclosure.

FIG. 5 is a view illustrating a unit frame and dicing lines of a semiconductor wafer according to an embodiment of the present disclosure.

FIG. 6 and FIG. 7 are views illustrating frame identifiers according to an embodiment of the present disclosure.

FIG. 8A and FIG. 8B are views illustrating frame identifiers according to an embodiment of the present disclosure.

FIG. 9 is a view illustrating a unit frame and dicing lines of a semiconductor wafer according to an embodiment of the present disclosure.

FIG. 10A to FIG. 10C are cross-sectional views illustrating a frame identifier according to an embodiment of the present disclosure.

FIG. 11A to FIG. 11C are cross-sectional views illustrating a frame identifier according to an embodiment of the present disclosure.

FIG. 12 is a flowchart illustrating a method of processing a semiconductor wafer according to an embodiment of the present disclosure.

FIG. 13 is a flowchart illustrating a method of determining positions of dicing lines according to an embodiment.

FIG. 14 is a flowchart illustrating a method of determining process conditions for dicing lines according to an embodiment.

FIG. 15 is a plan view illustrating unit frames and dicing lines on a semiconductor wafer according to an embodiment of the present disclosure.

FIG. 16 through FIG. 19 are flowcharts illustrating a method of processing a semiconductor wafer according to an embodiment of the present disclosure.

FIG. 20A to FIG. 20D are views illustrating semiconductor chips according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “connected” to another element, the elements may be connected directly or through an intervening element between the elements. When two elements are identified as “directly connected,” one element is directly connected to the other element without an intervening element between the two elements.

Terms such as “bottom,” “above,” “below,” “under,” “over,” “on,” “left,” “side,” “outside,” “upper,” “lower,” “higher,” “column,” “row,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

With regard to the process sequence of the wafer dicing, wafer back-grinding may be performed after half-sawing the wafer, compared to known methods of performing wafer sawing after wafer back-grinding. Half-sawing the wafer may include laser stealth dicing, which cuts off internal regions of the semiconductor wafer using laser energy.

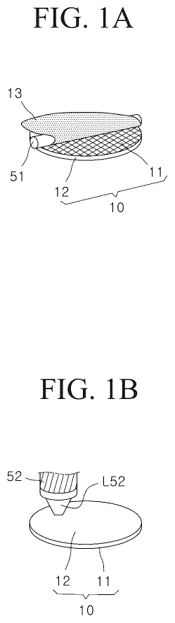

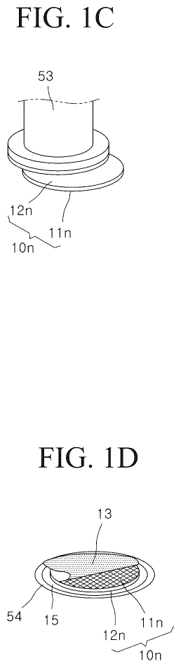

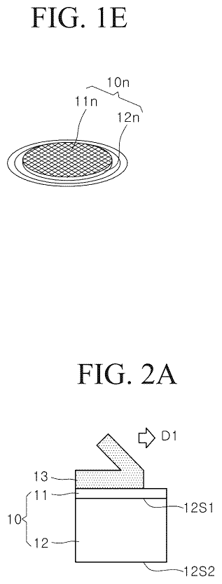

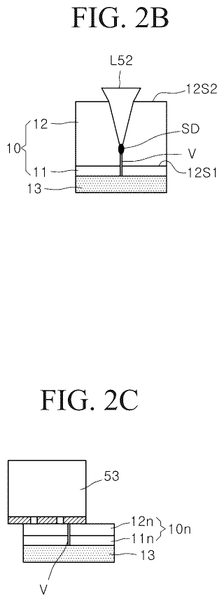

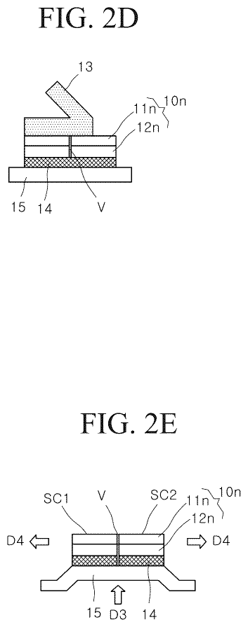

FIG. 1A to FIG. 1E illustrates perspective views of a wafer during a wafer processing process according to an embodiment of the present disclosure. FIG. 2A to FIG. 2E illustrate cross-sectional views of a wafer during the wafer processing process. In an embodiment, the wafer processing process described with respect to FIG. 1A to FIG. 1E and FIG. 2A to FIG. 2E may be a wafer dicing process including a process involving stealth dicing before grinding SDBG.

Referring to FIG. 1A and FIG. 2A, a semiconductor wafer 10 is formed including a substrate 12 having an upper surface 12S1, a lower surface 12S2, and an integrated circuit structure 11 formed on the upper surface 12S1 of the substrate 12. A protective tape 13 covering the integrated circuit structure 11 is laminated along a direction D1 on the upper surface 12S1 using a roller 51.

Referring to of FIG. 1B and FIG. 2B, stealth dicing is performed on the semiconductor wafer 10 using a laser device 52. Stealth dicing may be performed by irradiating laser light L52 from the lower surface 12S2 of the substrate 12 into an internal region of the substrate 12. Stealth dicing may be performed by irradiating the laser light L52 on the semiconductor wafer 10 along a given direction. Stealth dicing partitions the integrated circuit structure 11 such that semiconductor chip regions are separated from one another.

The laser light L52 forms a modified layer SD in the internal region of the substrate 12 and generates a crack V in an adjacent region of the modified layer SD. Then, the crack V progresses to the integrated circuit structure 11 and divides the integrated circuit structure 11. The integrated circuit structure 11 is divided into individual semiconductor chip regions.

For example, thermal expansion may occur in both lateral directions in the modified layer SD due to irradiation with the laser light L52. The thermal expansion generates tensile stress in both lateral directions with respect to the substrate 12 and the integrated circuit structure 11. The crack V is generated by the tensile stress that divides the integrated circuit structure 11.

Referring to FIG. 1C and FIG. 2C, the substrate 12 is polished from the lower surface 12S2 using a polishing device 53. The polishing process is performed until the crack V formed within the substrate 12 is exposed. Due to the polishing process, the thickness of substrate 12 is reduced, resulting in device substrate 12n. A device wafer 10n is manufactured including a plurality of semiconductor chip regions 11n separated from each other on a surface of the device substrate 12n.

Referring to FIG. 1D and FIG. 2D, the device wafer 10n is mounted on dicing tape 15. The dicing tape 15 is fixed by a fixing frame 54. In an embodiment, the process of mounting the device wafer 10n on the dicing tape 15 is performed by attaching a die attach film 14 to the surface of the device substrate 12n, and bonding the die attach film 14 to the dicing tape 15. In an embodiment, the surface of the device substrate 12n is bonded to the dicing tape 15 without using the die attach film 14. The protective tape 13 positioned on the plurality of semiconductor chip regions 11n is detached along a direction D2.

Referring to FIG. 1E and FIG. 2E, a force is applied in an upward direction D3 to the bottom of the dicing tape 15. As a result of the applied force, the dicing tape 15 expands in a lateral direction D4, such that the device wafer 10n including the semiconductor chip regions 11n is divided into unit semiconductor chips SC1 and SC2.

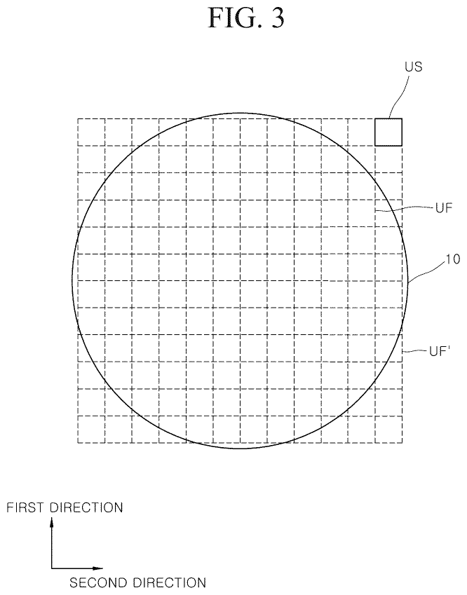

FIG. 3 is a plan view illustrating a semiconductor wafer 10 according to an embodiment of the present disclosure. Referring to FIG. 3, a semiconductor integration process, that may include a lithography process, repeatedly forms the same pattern on the semiconductor wafer 10 in units of frame shots US. After the semiconductor integration process is completed, the semiconductor wafer 10 includes a plurality of unit frames UF that are repeatedly arranged along a first direction and a second direction. The plurality of unit frames UF are arranged regularly, and the configurations of semiconductor integrated circuits arranged within the plurality of unit frames UF may be substantially identical. As illustrated in FIG. 3, when the patterns of the frame shots US are not transferred as a whole to the unit frames UF′ positioned along an edge of the semiconductor wafer 10, the unit frames UF′ positioned along the edge have an incomplete integrated circuit configuration.

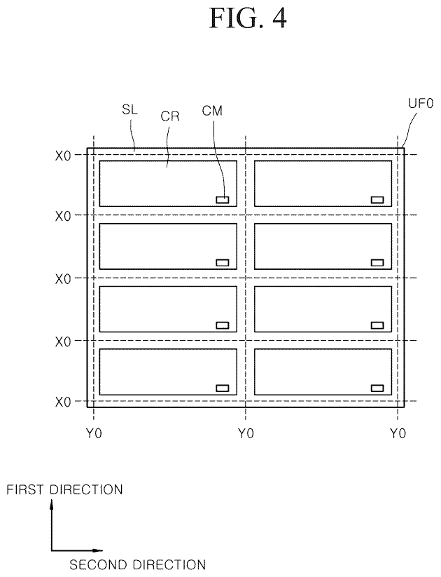

FIG. 4 is a view illustrating a unit frame UF0 and dicing lines for a semiconductor wafer according to an example of the present disclosure. The unit frame UF0 illustrated in FIG. 4 corresponds to the unit frame UF of the semiconductor wafer 10 described with reference to FIG. 3.

Referring to FIG. 4, the unit frame UF0 includes a plurality of chip regions CR regularly arranged along the first direction and the second direction and a scribe lane SL arranged outside the plurality of chip regions CR. The chip regions CR include integrated circuits constituting an electronic device in a chip unit. The scribe lane SL is a region surrounding the chip region CR. Various types of test patterns for evaluating process characteristics or device characteristics of the integrated circuits may be disposed in the scribe lane SL. A guard structure may be disposed at a boundary between the scribe lane SL and the chip regions CR. Patterns applied to the photolithography process, such as photo alignment marks and an overlay marks, are disposed in the scribe lane SL.

The plurality of chip regions CR includes an integrated circuit that is typically substantially similar or identical among the chip regions CR. At least one of the plurality of chip regions CR includes an alignment mark CM. The alignment mark CM is, for example, an identification pattern positioned at a specific location within the chip region CR. As illustrated in FIG. 4, each of the plurality of chip regions CR includes the same alignment mark CM positioned at the same location. The chip region CR to which the alignment mark CM belongs may be identified according to the alignment mark CM. The size and shape of the chip regions CR may be determined based on the alignment mark CM.

After the process of forming the integrated circuits for the plurality of chip regions CR is completed, a separation process is performed on the plurality of chip regions CR described with reference to FIG. 1A to FIG. 1E and FIG. 2A to FIG. 2B. In this example, stealth dicing described with reference to FIG. 1B and FIG. 2B is performed.

According to an example, the lithography process is performed by units of a unit frame UF on the semiconductor wafer 10 of FIG. 3, although stealth dicing is performed along first stealth dicing lines X0 and second stealth dicing lines Y0 between the chip regions CR, as illustrated in FIG. 4, regardless of the unit frames UF.

Referring to FIG. 4, the first stealth dicing lines X0 are arranged at regular intervals along the first direction between the plurality of chip regions CR, and the second stealth dicing lines Y0 are arranged at regular intervals along the second direction between the plurality of chip regions CR. When the size and shape of one of the chip regions CR are determined through identification of an alignment mark CM, the positions of the first stealth dicing lines X0 and the second stealth dicing lines Y0 are located based on the determined size and shape of the chip region CR. Stealth dicing may be performed under a first dicing condition along the first stealth dicing lines X0 and may be performed under a second dicing condition along the second stealth dicing lines Y0.

As described, various types of test patterns, photo alignment marks, and overlay marks may be arranged in the scribe lane SL of the unit frame UF0. In contrast to integrated circuits arranged at the same position within each of the plurality of chip regions CR, the test patterns, the photo align marks, and the overlay marks may be arranged in a specific region of the scribe lane SL within the unit frame UF0. That is, the arrangement or orientation of the test pattern, photo alignment mark, and overlay mark adjacent to or near one chip within the unit frame UF0 may not be the same as the arrangement or orientation of the test pattern, photo alignment mark, and overlay mark adjacent to or near another chip. Accordingly, the material composition of the scribe lane SL where the stealth dicing lines X0 and Y0 intersect may be different for various locations in the unit frame UF0 according to the types of the test pattern and dummy pattern.

Stealth dicing may have different dividing characteristics depending on the properties of dicing target materials. When stealth dicing is performed under the similar process conditions, un-division or excessive division may occur in one or more of the stealth dicing lines X0 and Y0. Un-division occurrence causes dicing defects, and excessive division occurrence causes excessive thermal expansion in the semiconductor wafer on which stealth dicing is performed, which may worsen the wafer warpage. When wafer warpage occurs excessively, process defects often occur during the subsequent back-grinding process.

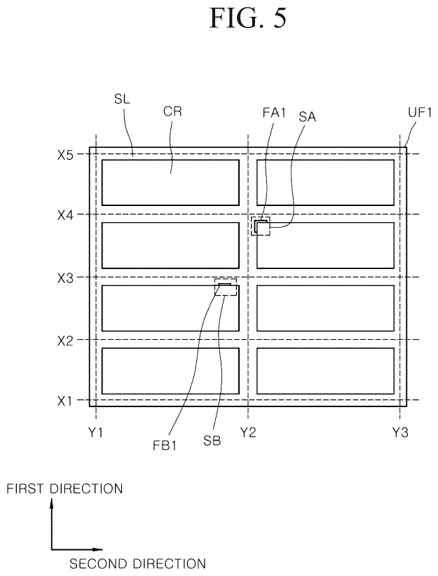

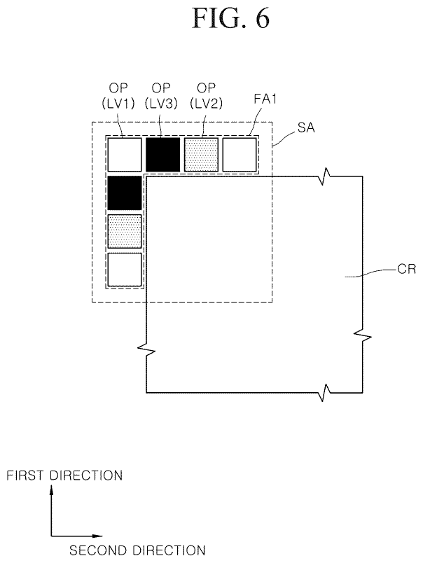

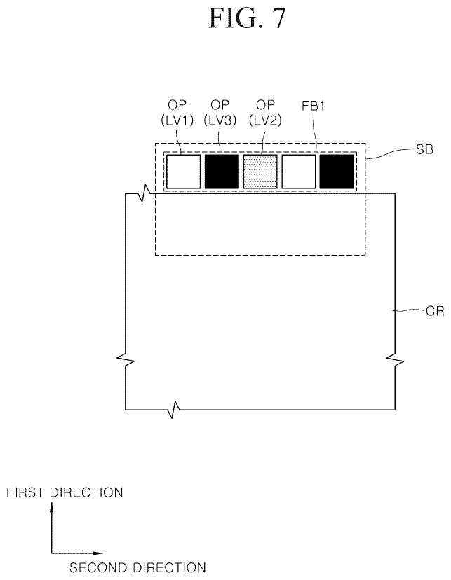

FIG. 5 is a view illustrating a unit frame UF1 and dicing lines of a semiconductor wafer according to an embodiment of the present disclosure. The unit frame UF1 illustrated in FIG. 5 corresponds to the unit frame UF of the semiconductor wafer 10 described with reference to FIG. 3. FIG. 6 and FIG. 7 are views illustrating frame identifiers FA1 and FB1 according to an embodiment of the present disclosure. FIG. 6 illustrates an enlarged view of the frame identifier FA1 arranged in a first region SA of the unit frame UF1 of FIG. 5. FIG. 7 illustrates an enlarged view of the frame identifier FB1 arranged in a second region SB of the unit frame UF1 of FIG. 5.

Referring to FIG. 5, the unit frame UF1 includes a plurality of chip regions CRs and a scribe lane SL disposed outside of the plurality of chip regions CR. The scribe lane SL surrounds the plurality of chip regions CR. The unit frame UF1 includes the frame identifiers FA1 and FB1 located in the scribe lane SL.

The frame identifiers FA1 and FB1 are arranged at different locations and orientations within the unit frame UF1. The first frame identifier FA1 has a different shape than the shape of the second frame identifier FB1. For example, as illustrated in FIG. 5, the first frame identifier FA1 has an L shape, and the second frame identifier FB1 has a straight shape.

In an embodiment, the frame identifier may be disposed as a single identifier within the unit frame UF1. The frame identifier may be the first frame identifier FA1 or the second frame identifier FB1 of FIG. 5, for example. In an embodiment, three or more frame identifiers may be located at different positions within the unit frame UF1. In this example, the three or more identifiers may have two or more different shapes.

Referring to FIG. 5, a plurality of dicing lines X1, X2, X3, X4, X5, Y1, Y2, and Y3 are established in the scribe lane SL for dicing during separation of the plurality of chip regions CR. The plurality of dicing lines X1, X2, X3, X4, X5, Y1, Y2, and Y3 include a first dicing line X1, a second dicing line X2, a third dicing line X3, a fourth dicing line X4, and a fifth dicing line X5 arranged at regular intervals along the first direction and a sixth dicing line Y1, a seventh dicing line Y2, and an eight dicing line Y3 arranged at regular intervals along the second direction. In an embodiment, the frame identifiers FA1 and FB1 are spaced apart from the plurality of dicing lines X1, X2, X3, X4, X5, Y1, Y2, and Y3 in the scribe lane SL.

In an embodiment, the frame identifiers FA1 and FB1 provide references that identify the positions of the plurality of dicing lines X1, X2, X3, X4, X5, Y1, Y2, and Y3. The relative positions of the plurality of dicing lines X1, X2, X3, X4, X5, Y1, Y2, and Y3 within the unit frame UF1 are determined based on the frame identifiers FA1 and FB1. Thus, the positions of the plurality of dicing lines X1, X2, X3, X4, X5, Y1, Y2, and Y3 are identified based on the frame identifiers FA1 and FB1.

When the plurality of frame identifiers FA1 and FB1 are arranged within the unit frame UF1, the plurality of frame identifiers FA1 and FB1 may function according to priority. For example, when the first frame identifier FA1 has a higher priority among the frame identifiers FA1 and FB1, the first frame identifier FA1 is utilized as the identification reference before utilizing the second frame identifier FB1. When the first frame identifier FA1 fails to provide a proper identification reference, the second frame identifier FB1 is utilized as the identification reference in place of the first frame identifier FA1.

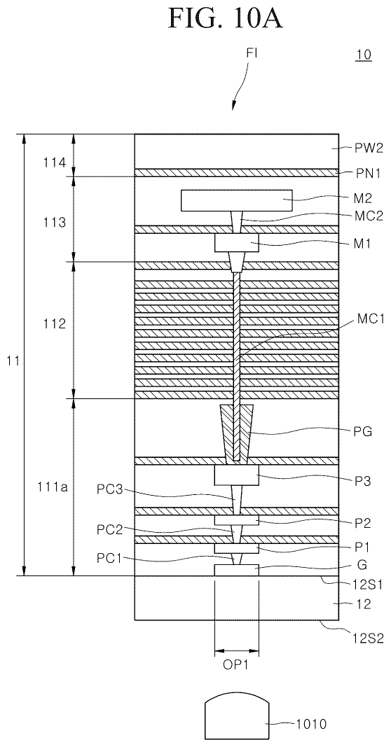

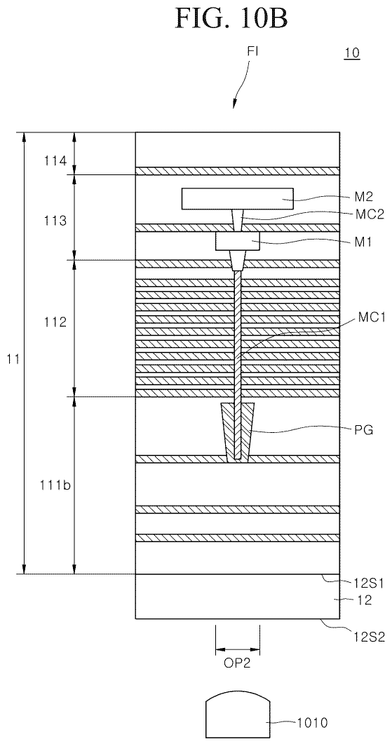

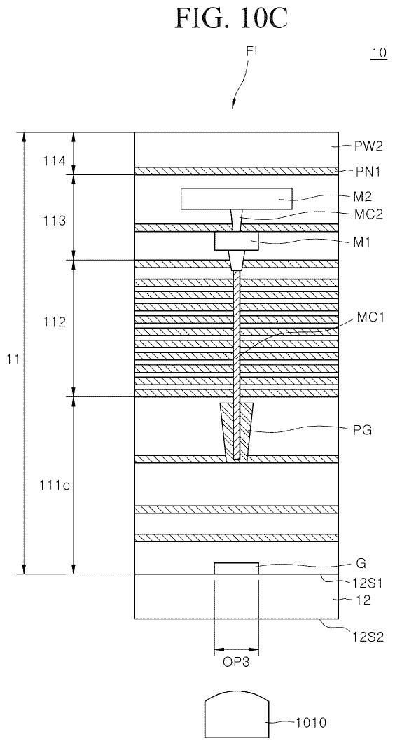

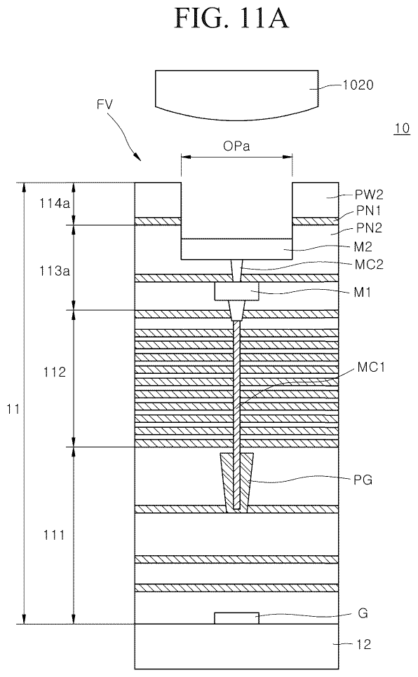

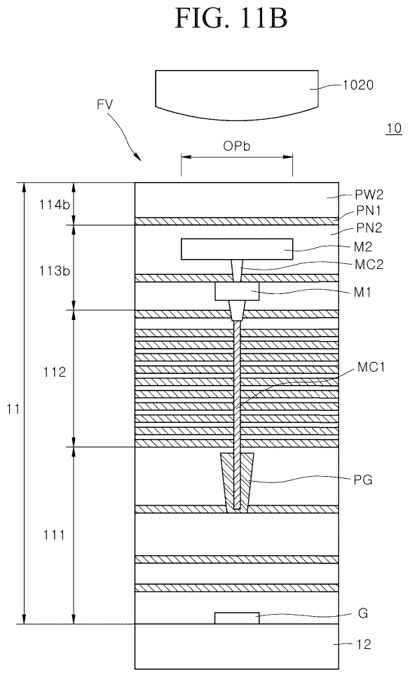

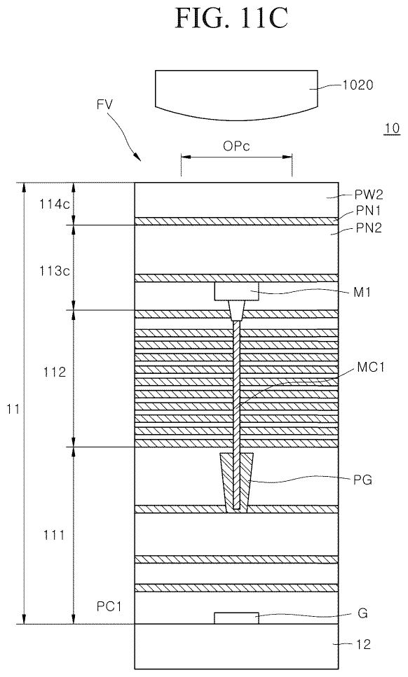

In an embodiment, the frame identifiers FA1 and FB1 may be identified as infrared patterns utilizing infrared rays irradiated, from below the semiconductor wafer 10 of FIG. 3, on the lower surface of the semiconductor wafer 10. The infrared patterns are described in detail with reference to FIG. 10A to FIG. 10C. In another embodiment, the frame identifiers FA1 and FB1 may be identified as visible light patterns by visible light irradiated on the semiconductor wafer 10 from above the semiconductor wafer 10 of FIG. 3. The visible light patterns are described in detail with reference to FIG. 11A to FIG. 11C.

Referring to FIG. 5, the first frame identifier FA1 arranged in the first region SA of the unit frame UF1 is disposed in the scribe lane SL adjacent to or near an upper left corner where a long side and a short side of the chip region CR meet. Referring to FIG. 6, the first frame identifier FA1 includes a plurality of optical patterns OP arranged respectively along a first direction and a second direction of the chip region CR. The plurality of optical patterns OP are arranged near or adjacent to each other and have the same shape. The plurality of optical patterns OP are depicted as square patterns having the same size, such as width and length. The plurality of optical patterns OP may include circular patterns or polygonal patterns having the same size and shape. The plurality of optical patterns OP may be distinguished from one another by differences in brightness, for example, as described with respect to FIG. 10A, FIG. 10B, FIG. 10C, FIG. 11A, FIG. 11B, and FIG. 11C. For example, as illustrated in FIG. 6, each optical pattern OP is associated with a brightness grade including one of a first level LV1, a second level LV2, and a third level LV3. The brightness levels are distinguishable or identifiable among consecutive optical patterns OP of a frame identifier. The number of brightness levels is not limited to three. The plurality of optical patterns OP are associated with a different number of brightness levels within a range in which a difference in brightness between consecutive optical patterns OP may be identified.

Referring to FIG. 5, the second frame identifier FB1 may be disposed in the scribe lane SL adjacent to the long side or the short side of the chip region CR. In an embodiment, as illustrated in FIG. 7, the second frame identifier FB1 includes a plurality of optical patterns OP arranged along the second direction of the chip region CR. For example, each of the plurality of optical patterns OP is associated with a brightness grade including one of the first level LV1, the second level LV2, and the third level LV3. The brightness levels are distinguishable or identifiable between consecutive optical patterns OP, for example, as described with respect to FIG. 10A, FIG. 10B, FIG. 10C, FIG. 11A, FIG. 11B, and FIG. 11C. In another example not illustrated, the second frame identifier FB1 may include a plurality of optical patterns OP arranged along the first direction of the chip region CR and identified by differences in brightness.

Referring to FIG. 6 and FIG. 7, the plurality of optical patterns OP form the frame identifiers FA1 and FB1 as a group. The frame identifiers FA1 and FB1 are pattern that are distinct from the integrated structure disposed in the scribe lane SL adjacent to the corresponding chip region CR. As described, the frame identifiers FA1 and FB1 may include check or grid patterns including a plurality of optical patterns OP that are distinguished from one another by difference in brightness, for example, as described with respect to FIG. 10A, FIG. 10B, FIG. 10C, FIG. 11A, FIG. 11B, and FIG. 11C.

According to an embodiment of the present disclosure, when performing a dicing process on the semiconductor wafer 10 of FIG. 3, the relative positions of the plurality of dicing lines X1, X2, X3, X4, X5, Y1, Y2, and Y3 within the unit frame UF1 of the semiconductor wafer 10 can be identified using the frame identifiers FA1 and FB1 of FIG. 5. The method is differentiated from the example described with reference to FIG. 4 because the relative positions of the plurality of dicing lines within the unit frame UF0 are not identified with each other during the dicing process.

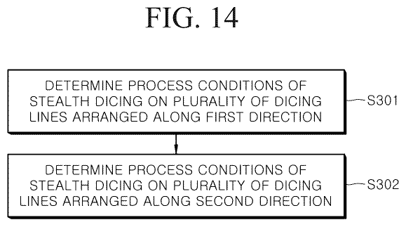

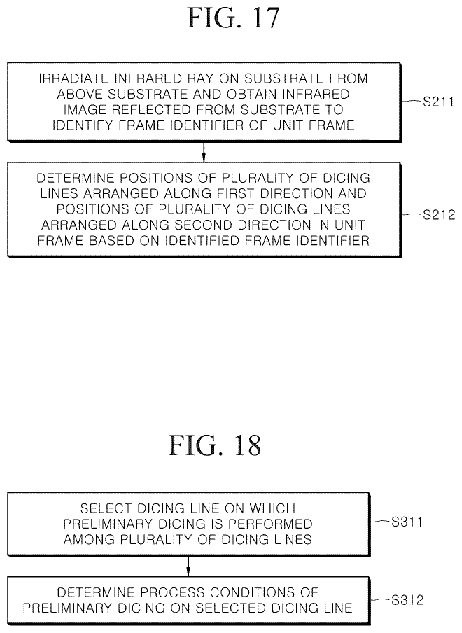

According to an embodiment of the present disclosure, the process conditions of the dicing process are determined for at least one of the plurality of dicing lines X1, X2, X3, X4, X5, Y1, Y2, and Y3. The dicing process of the semiconductor wafer 10 is performed with the process conditions determined for one or more of the plurality of dicing lines X1, X2, X3, X4, X5, Y1, Y2, and Y3. The dicing process may include, for example, stealth dicing, as described with reference to FIG. 13 and FIG. 14, blade sawing, or laser grooving as described with reference to FIG. 17 to FIG. 19. The dicing process of the semiconductor wafer 10 is differentiated from the dicing process of the example described with reference to FIG. 4 in which the dicing process of the first stealth dicing lines X0 is performed under the same process conditions, and the dicing process of the second stealth dicing lines Y0 is performed under the same process conditions.

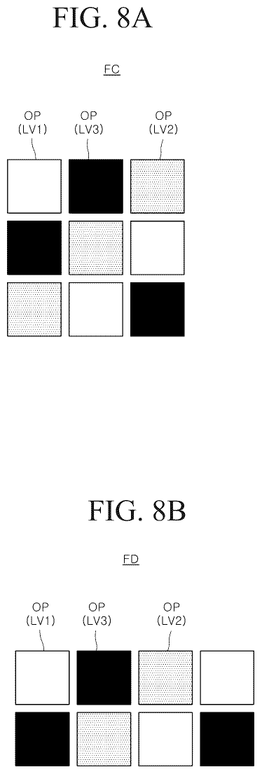

FIG. 8A and FIG. 8B are views illustrating frame identifiers FC and FD according to an embodiment of the present disclosure. The frame identifiers FC and FD illustrated in FIG. 8A and FIG. 8B, respectively, have different shapes from the frame identifiers FA1 and FB1 described with reference to FIG. 5 to FIG. 7.

The frame identifier FC of FIG. 8A has nine optical patterns OP arranged in three rows and three columns. The frame identifier FD of FIG. 8B has eight optical patterns OP arranged in two rows and four columns. Each optical pattern OP incorporated within the frame identifiers FC and FD is associated with a brightness grade including one of the first level LV1, the second level LV2, and the third level LV3. The brightness levels are distinguishable or identifiable by a difference in brightness. The plurality of optical patterns OP are incorporated in the frame identifiers FC and FD that have a check or grid pattern. Thus, each of the frame identifiers FC and FD includes a check or grid pattern including a plurality of optical patterns OP that are distinguished from one another by a difference in brightness, for example, as described with respect to FIG. 10A, FIG. 10B, FIG. 10C, FIG. 11A, FIG. 11B, and FIG. 11C. The check or grid pattern may be symmetrical or asymmetrical. The position where the frame identifier FC of FIG. 8A is arranged within the unit frame may be the position of the first frame identifier FA1 as shown in FIG. 5 and FIG. 6, for example, in the scribe lane SL adjacent to the upper left corner of the chip region CR where a long side and a short side of the chip region CR meet. Alternatively, the position where the frame identifier FC of FIG. 8A is arranged within the unit frame may be the position of the second frame identifier FB1 as shown in FIG. 5 and FIG. 7, for example, in the scribe lane SL adjacent to one of the long side or short side of the chip region CR. The position where the frame identifier FD of FIG. 8B is arranged may be substantially the same as the position of the first frame identifier FA1 of FIG. 5 and FIG. 6 or the position of the second frame identifier FB1 of FIG. 5 and FIG. 7.

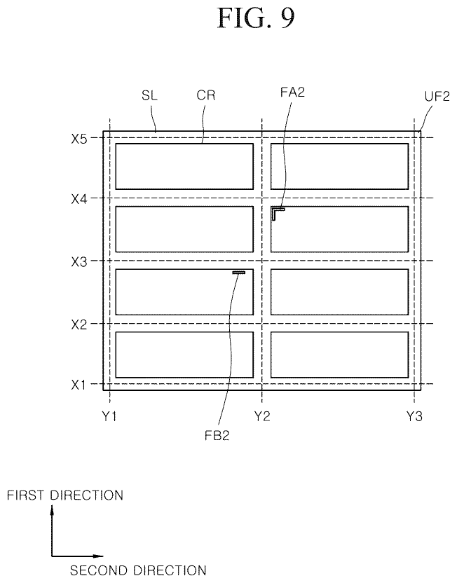

FIG. 9 is a view illustrating a unit frame UF2 and dicing lines of a semiconductor wafer according to an embodiment of the present disclosure. The unit frame UF2 illustrated in FIG. 9 corresponds to the unit frame UF of the semiconductor wafer 10 described with respect to FIG. 3.

Referring to FIG. 9, the unit frame UF2 includes a plurality of chip regions CR and a scribe lane SL disposed outside of or surrounding the plurality of chip regions CR. The unit frame UF2 includes frame identifiers FA2 and FB2 located within the plurality of chip regions CR.

The frame identifiers FA2 and FB2 are disposed at different positions and orientations within the unit frame UF2. The third frame identifier FA2 is disposed inside the chip region CR near the upper left corner of the chip region CR where a long side and a short side of the chip region CR meet. The fourth frame identifier FB2 is disposed along an edge inside the chip region CR, for example, along the long side as shown in FIG. 9 or along the short side of the chip region CR. In an embodiment, the chip region CR includes a cell arrangement area and a peripheral circuit arrangement area. The frame identifiers FA2 and FB2 may be arranged in the peripheral circuit arrangement area. As illustrated in FIG. 9, the identifiers FA2 and FB2 are spaced apart from the plurality of dicing lines X1, X2, X3, X4, X5, Y1, Y2, and Y3.

The third identifier FA2 and the fourth identifier FB2 include a plurality of optical patterns associated with differences in brightness, for example, as described with respect to FIG. 10A, FIG. 10B, FIG. 10C, FIG. 11A, FIG. 11B, and FIG. 11C. The configuration of the plurality of optical patterns may be substantially the same as the configuration of the plurality of optical patterns OP described with reference to FIG. 6, FIG. 7, FIG. 8A and FIG. 8B.

In FIG. 9, the third frame identifier FA2 has a different shape than shape of the fourth frame identifier FB2. In an embodiment, the frame identifier may be a single identifier within the unit frame UF2 or may include three or more identifiers having two or more different shapes.

FIG. 10A to FIG. 10C are cross-sectional views illustrating a frame identifier FI according to an embodiment of the present disclosure. FIG. 10A to FIG. 10C are cross-sectional views illustrating the structure of the frame identifier FI disposed on a semiconductor wafer 10 when a NAND memory device is formed on the semiconductor wafer 10. The frame identifier FI includes a first optical pattern OP1, a second optical pattern OP2, and a third optical pattern OP3 that are associated with different brightness levels. The optical patterns OP1, OP2, and OP3 are disposed consecutively and may follow the planar arrangement of the plurality of optical patterns OPs described, for example, with reference to FIG. 6, FIG. 7, FIG. 8A, and FIG. 8B. Different cross-sectional structures of the first optical pattern OP1, the second optical pattern OP2, and the third optical pattern OP3 are described with reference to FIG. 10A, FIG. 10B, and FIG. 10C.

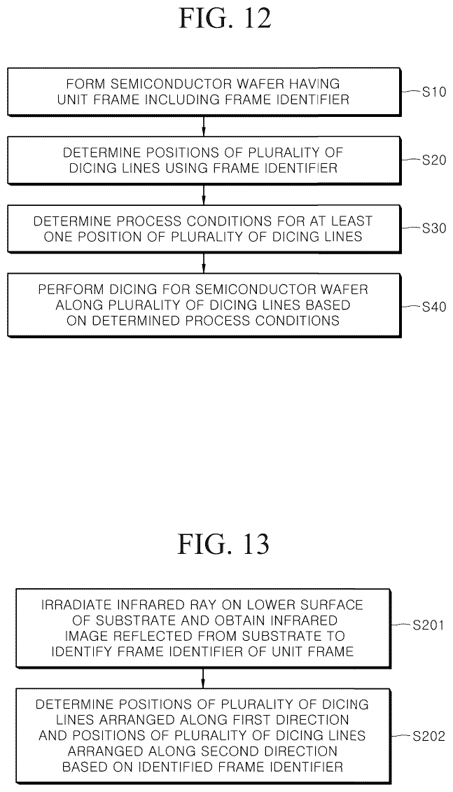

Referring to FIG. 10A to FIG. 10C, the frame identifier FI is identified as an infrared pattern by an inspection device, such as an infrared inspection device 1010. For example, the infrared inspection device 1010 includes an infrared irradiation device, an infrared image capturing device, and an image identification device. The infrared irradiation device irradiates infrared rays on a lower surface 12S2 of a substrate 12, and the infrared image capturing device obtains the infrared rays reflected by an integrated circuit structure inside the semiconductor wafer 10 in the form of an image. The image identification device identifies the frame identifier FI by comparing the obtained infrared image with a pre-stored standard image. The frame identifier FI may be utilized during stealth dicing described with reference to FIG. 12 to FIG. 14.

The frame identifier FI includes the substrate 12 and an integrated circuit structure 11 disposed on the substrate 12. The integrated circuit structure 11 includes first structures 111a, 111b, and 111c, a second structure 112, a third structure 113, and a fourth structure 114 that are sequentially disposed on the substrate 12. The second structure 112 may be a memory cell structure arranged in the cell region CR. The first structures 111a, 111b, and 111c are arranged below the second structure 112 and may be peripheral circuit structures of the cell region CR configured to electrically control or drive the memory cell structure. The third structure 113 may be an interconnection structure for the cell region CR, which electrically interconnects the memory cell structures or connects the memory cell structure to the peripheral circuit structures. For example, the third structure 113 includes first interconnection line M1 and second interconnection line M2. A contact MC1 electrically connects the first interconnection line M1 to a metal layer of the first structures 111a, 111b, and 111c. A via MC2 electrically connects the first interconnection line M1 to the second interconnection line M2. The fourth structure 114 may be a passivation structure for the cell region CR, which protects the first structures 111a, 111b, 111c, the second structure 112, and the third structure 113.

As illustrated in FIG. 10A to FIG. 10C, the optical patterns OP1, OP2, and OP3 of the frame identifier FI include differing stack structures. In an embodiment, the optical patterns OP1, OP2, and OP3 include the first structures 111a, 111b, and 111c, respectively, incorporating different stack structures. Referring to FIG. 10A, the first structure 111a of the first optical pattern OP1 includes a gate electrode layer G disposed on the substrate 12. The first structure 111a includes a first lower metal layer P1, a second lower metal layer P2, and a third lower metal layer P3 arranged at different distances from the gate electrode layer G. The first structure 111a includes a first lower contact PC1 connecting the gate electrode layer G to the first lower metal layer P1, a second lower contact PC2 connecting the first lower metal layer P1 to the second lower metal layer P2, and a third lower contact PC3 connecting the second lower metal layer P2 to the third lower metal layer P3. The first structure 111a includes a contact plug PG disposed on the third lower metal layer P3.

Referring to FIG. 10B, the first structure 111b of the second optical pattern OP2 does not include the gate electrode layer G, the lower metal layers P1, P2, and P3, and the lower contacts PC1, PC2, and PC3 from the first structure 111a of the first optical pattern OP1. Referring to FIG. 10C, the first structure 111c of the third optical pattern OP3 includes the gate electrode layer G but does not include the lower metal layers P1, P2, and P3 and the lower contacts PC1, PC2, and PC3 from the first structure 111a of the first optical pattern OP1.

Referring to FIG. 10A to FIG. 10C, the infrared ray incident on the lower surface 12S2 of the substrate 12 exhibits different light reflection characteristics or light transmission characteristics due to the structural differences between the first structures 111a, 111b, and 111c. Different brightness levels are present in the images of reflected light received by the infrared inspection device 1010. For example, the first optical pattern OP1 including the lower metal layers P1, P2, and P3 made of a metal material having relatively higher infrared reflection properties generates a brighter image than the second optical pattern OP2 and the third optical pattern OP3 that have relatively lower infrared reflective properties. The third optical pattern OP3 including a gate electrode layer G made of a material having a higher absorption rate for infrared rays generates a darker image than the second optical pattern OP2 not including the gate electrode layer G.

With reference to FIG. 10A to FIG. 10C, the differences in brightness between the optical patterns OP1, OP2, and OP3 may be generated using different stack structures for the first structures 111a, 111b, and 111c, although the present disclosure is not limited to this example. In an embodiment, the stack structures of other structures, such as the second structure 112, may be varied in addition to the first structures 111a, 111b, and 111c to generate differences in brightness associated with the optical patterns OP1, OP2, and OP3.

FIG. 11A to FIG. 11C are cross-sectional views illustrating a frame identifier FV according to an embodiment of the present disclosure. FIG. 11A to FIG. 11C are views illustrating the cross-sectional structures of the frame identifier FV disposed on a semiconductor wafer 10 when a NAND memory device is formed on the semiconductor wafer 10. The frame identifier FV includes a first optical pattern OPa, a second optical pattern OPb, and a third optical pattern OPc that are associated with different brightness levels. The optical patterns OPa, OPb, and OPc are arranged consecutively and follow a planar arrangement of the plurality of optical patterns OP described, for example, with reference to FIG. 6, FIG. 7, FIG. 8A, and FIG. 8B. Different cross-sectional structures of the first optical pattern OPa, the second optical pattern OPb, and the third optical pattern OPc are described with reference to FIG. 11A, FIG. 11B, and FIG. 11C.

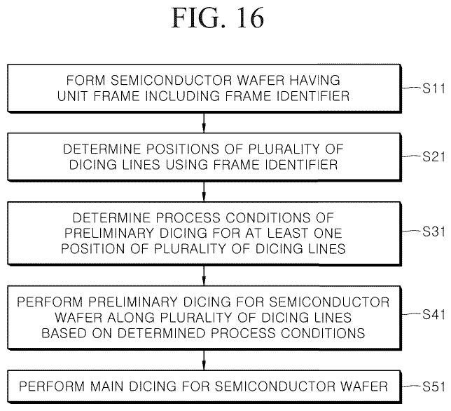

Referring to FIG. 11A to FIG. 11C, the frame identifier FV can be identified as a visible light pattern by a visible light inspection device 1020. In an embodiment, the visible light inspection device 1020 includes a visible light irradiation device, a visible light image capturing device, and an image identification device. The light irradiation device irradiates visible light on an integrated circuit structure 11 from above a semiconductor wafer 10, and the visible light image capturing device obtains the visible light reflected by the integrated circuit structure inside the semiconductor wafer 10 in the form of an image. The image identification device identifies the frame identifiers FV by comparing the obtained visible light image with a pre-stored standard image. The frame identifier FV may be utilized during preliminary dicing described with reference to FIG. 16 to FIG. 18.

The frame identifier FV includes the substrate 12 and the integrated circuit structure 11 disposed on the substrate 12. The integrated circuit structure 11 includes a first structure 111, a second structure 112, third structures 113a, 113b, and 113c, and fourth structures 114a, 114b, and 114c that are sequentially stacked over the substrate 12. The optical patterns OPa, OPb, and OPc of the frame identifier FV have different stack structures including the third structures 113a, 113b, and 113c and the fourth structures 114a, 114b, and 114c, respectively.

Referring to FIG. 11A, in the example of the first optical pattern OPa, sections of a second interlayer insulating layer PW2 and a first interlayer insulating layer PN1 of the fourth structure 114a and a interlayer insulating layer PN2 of the third structure 113a are patterned such that a second interconnection line M2 made of a metal or conductive material is exposed. Referring to FIG. 11B, comparing the second optical pattern OPb to the first optical pattern OPa, the upper portion of the second interconnection line M2 is covered by the interlayer insulating layer PN2 of the third structure 113b and the first and second interlayer insulating layers PN1 and PW2 of the fourth structure 114b. Referring to FIG. 11C, comparing the third optical pattern OPc to the first optical pattern OPa, the third structure 113c does not include the second interconnection line M2 and the via MC2.

Referring to FIG. 11A to FIG. 11C, the visible light emitted by the visible light inspection device 1020 and incident on the integrated circuit structure 11 from above the semiconductor wafer 10 results in different light reflection and light transmission characteristics due to the structural differences among the third structures 113a, 113b, and 113c and the fourth structures 114a, 114b, and 114c. Consequently, differences in brightness occur in the images resulting from the reflected light obtained by the visible light inspection device 1020. For example, the first optical pattern OPa including the second interconnection line M2 that is exposed and made of a metal material with relatively higher reflective properties for visible light generates a brighter image than the second optical pattern OPb and the third optical pattern OPc that have relatively lower reflective properties for visible light. The second optical pattern OPb including the second interconnection line M2 and the via MC2 made of a metal material generates a brighter image than the third optical pattern OPc that does not include the second interconnection line M2 and the via MC2.

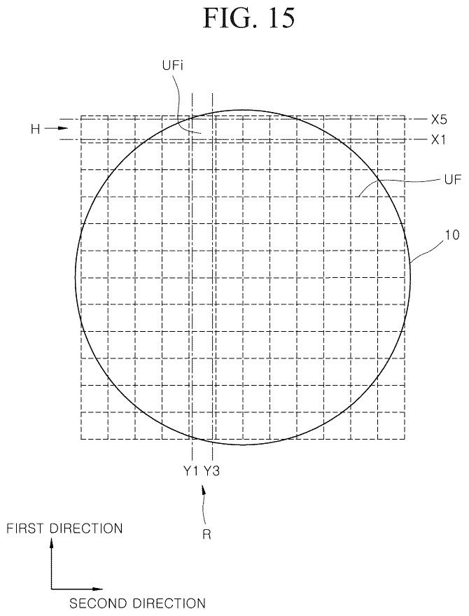

FIG. 12 is a flowchart illustrating a method of processing a semiconductor wafer according to an embodiment of the present disclosure. FIG. 13 is a flowchart illustrating a method of determining positions of dicing lines according to an embodiment. FIG. 14 is a flowchart illustrating a method of determining process conditions for dicing lines according to an embodiment. The processes of the flowcharts may be performed in a different order and may include fewer or additional processes than described and shown in FIG. 12 through FIG. 14. FIG. 15 is a plan view illustrating unit frames and dicing lines on a semiconductor wafer according to an embodiment of the present disclosure. In an embodiment, the method of processing the semiconductor wafer illustrated in FIG. 12 to FIG. 15 may be utilized during a wafer dicing process including the SDBG process described with reference to FIG. 1A to FIG. 1E and FIG. 2A to FIG. 2E.

Referring to FIG. 12, a semiconductor wafer having a unit frame is formed S10 including a frame identifier. In an embodiment, the frame identifier is utilized during stealth dicing. The frame identifier may be identified as an infrared pattern.

In an embodiment, the semiconductor wafer 10 of FIG. 3 including the unit frame UF1 of FIG. 5 or the unit frame UF2 of FIG. 9 is formed. The unit frame UF1 and the unit frame UF2 include, for example, the frame identifier FA1 of FIG. 6, the frame identifier FB1 of FIG. 7, the frame identifier FC of FIG. 8A, the frame identifier FD of FIG. 8B, or the frame identifiers FA2 and FB2 of FIG. 9.

In an embodiment, the optical pattern OP of the frame identifiers FA1, FB1, FA2, FB2, FC, and FD may be substantially similar to one of the optical patterns OP1, OP2, and OP3 described with reference to FIG. 10A to FIG. 10C.

Referring to FIG. 12, the positions of the plurality of dicing lines are determined S20 using the frame identifier. The plurality of dicing lines may be dicing lines utilized during stealth dicing.

In an embodiment, in the semiconductor wafer 10, the frame identifiers FA1, FB1, FA2, FB2, FC, and FD of the unit frames UF1 and UF2 are identified, and the relative positions of the plurality of dicing lines X1, X2, X3, X4, X5, Y1, Y2, and Y3 for stealth dicing are identified and determined based on the frame identifiers FA1, FB1, FA2, FB2, FC, and FD. The plurality of dicing lines X1, X2, X3, X4, X5, Y1, Y2, and Y3 are spaced apart from the frame identifiers FA1, FB1, FA2, FB2, FC, and FD. The process of determining the positions of the plurality of dicing lines is described in detail with respect to the flowchart of FIG. 13. Infrared rays are irradiated S201 from below the substrate on a lower surface of the substrate, and an image of the infrared rays reflected from the substrate is acquired to identify the frame identifiers of the unit frame. In an embodiment, as described with reference to FIG. 10A to FIG. 10C, the infrared inspection device 1010 irradiates infrared rays on the lower surface 12S2 of the substrate 12, and after the infrared rays are reflected by an integrated circuit structure of the semiconductor wafer 10, the infrared images are acquired by the infrared inspection device 1010. The frame identifier FI is identified using the infrared image.

Based on the identified frame identifier, the positions of the plurality of dicing lines arranged along the first direction and the positions of the plurality of dicing lines arranged along the second direction substantially perpendicular to the first direction within the unit frame are determined S202. In an embodiment, as described with reference to FIG. 5, during stealth dicing, the positions of the dicing lines X1, X2, X3, X4, and X5 arranged along the first direction and the dicing lines Y1, Y2, and Y3 arranged along the second direction are separately determined based on the size of the chip region CR and the frame identifiers FA1 and FB1 on the semiconductor wafer 10.

Referring to FIG. 12, process conditions of the dicing process are determined S30 for at least one position of the plurality of dicing lines. In an embodiment, determining the process conditions of the dicing process includes, with reference to the flowchart of FIG. 14, determining S301 the process conditions of stealth dicing for the plurality of dicing lines arranged along the first direction and determining S302 the process conditions of stealth dicing for the plurality of second dicing lines arranged along the second direction.

In an embodiment, the process conditions of stealth dicing may include, for example, laser power, frequency of laser light, scan speed of laser light, quantity of multiple modified layers formed in the substrate, spacing between the modified layers formed in the substrate, and positions of the modified layers within the substrate.

Referring to FIG. 12, based on the determined process conditions, the semiconductor wafer is diced S40 along the plurality of dicing lines. In an embodiment, referring to FIG. 15, when the process conditions of stealth dicing along the dicing lines X1, X2, X3, X4, X5, Y1, Y2, and Y3 are determined within the pre-designated unit frame UFi, and stealth dicing for the semiconductor wafer 10 is performed along the dicing lines X1, X2, X3, X4, X5, Y1, Y2, and Y3. For convenience of illustration, only the first dicing line X1 and the fifth dicing line X5 spaced apart along the first direction and the sixth dicing line Y1 and the eighth dicing line Y3 spaced apart along the second direction are illustrated in FIG. 15.

Referring to FIG. 15, for the plurality of unit frames located in the same row H as the pre-designated unit frame UFi, stealth dicing for the semiconductor wafer 10 is performed in batches along the first dicing line X1, and stealth dicing for the semiconductor wafer 10 is sequentially performed along the dicing lines X2, X3, X4, and X5. Stealth dicing for other rows is performed in the same manner.

For the plurality of unit frames located in the same column R as the pre-designated unit frame UFi, stealth dicing for the semiconductor wafer 10 is performed in batches along the sixth dicing line Y1, and stealth dicing for the semiconductor wafer 10 is sequentially performed along the dicing lines Y2 and Y3. Stealth dicing for other rows is performed in the same manner.

Although not illustrated in the flowchart of FIG. 12, in some embodiments, the method of processing the semiconductor wafer may further include comparing the positions of the plurality of dicing lines determined according to the frame identifiers with the positions of the plurality of chip cutting lines formed as a result of performing the dicing process. According to an embodiment of the present disclosure, the frame identifiers are located in the scribe lane or the chip regions, spaced apart from the plurality of dicing lines. The frame identifiers may remain after the dicing process without being damaged by the dicing process. Accordingly, the positions of the plurality of dicing lines set for the dicing process may be re-identified using the remaining frame identifiers. In addition, the positions of the plurality of re-identified dicing lines may be compared with the positions of the plurality of chip cutting lines formed after the dicing process. According to an embodiment, the method of processing the semiconductor wafer may further include correcting the position of the dicing line on which the subsequent dicing process is to be performed, based on the comparison result.

In an embodiment, correcting the position of the dicing line is performed while the dicing process for the semiconductor wafer 10 is in progress. For example, correcting the position of the dicing line may be performed in the following order with reference to FIG. 15. For the plurality of unit frames located in the same row H as the unit frame UFi, stealth dicing for the semiconductor wafer 10 is performed along the first dicing line X1 identified by the frame identifier. As described, because the frame identifier remains after stealth dicing, the position of the first dicing line X1 determined by the frame identifier may be compared with the position of the chip cutting line formed as a result of stealth dicing. Based on the comparison results, the position of the second dicing line X2 on which stealth dicing is performed may subsequently be corrected. Correcting the positions of the dicing lines may improve the process reliability of stealth dicing.

As described, according to an embodiment of the present disclosure, stealth dicing may be performed under different process conditions for one or more of the plurality of dicing lines that are distinguished from each other within a unit frame. Compared to performing stealth dicing under the same process condition for each of the plurality of dicing lines in the example of FIG. 4, in an embodiment of the present disclosure, stealth dicing may be performed by selectively strengthening the process conditions of stealth dicing for the dicing line where un-division occurs. Preventing excessive division from occurring in the semiconductor wafer is possible when the process conditions of stealth dicing are uniformly strengthened to overcome un-division occurrence. As a result, unwanted bending occurring in the semiconductor wafer due to the thermal expansion accompanying excessive division occurrence may be effectively prevented.

FIG. 16 through FIG. 19 are flowcharts illustrating a method of processing a semiconductor wafer according to an embodiment of the present disclosure. The processes of the flowcharts may be performed in a different order and may include fewer or additional processes than described and shown in FIG. 16 through FIG. 19. In an embodiment, the processing of the semiconductor wafer is performed in two stages: preliminary dicing and main dicing. Preliminary dicing is performed on selected dicing lines from among a plurality of dicing lines. The main dicing may be performed with stealth dicing on each of the plurality of stealth dicing lines under the same process condition.

Referring to FIG. 16, a semiconductor wafer having a unit frame including frame identifiers is formed S11. In an embodiment, the frame identifiers may be utilized during blade sawing or laser grooving. The frame identifiers may be identified as visible light patterns as described with respect with reference to FIG. 11A, FIG. 11B, and FIG. 11C.

In an embodiment, the semiconductor wafer 10 including the unit frame UF1 of FIG. 5 or the unit frame UF2 of FIG. 9 is formed. The unit frame UF1 and the unit frame UF2 include at least one of the frame identifier FA1 of FIG. 6, the frame identifier FB1 of FIG. 8, the frame identifier FC of FIG. 8A, the frame identifier FD of FIG. 8B, or the frame identifiers FA2 and FB2 of FIG. 9.

The frame identifiers FA1, FB1, FA2, FB2, FC, and FD include a plurality of optical patterns OP that can be identified by differences in brightness in response to visible light. The plurality of optical patterns OP may each correspond to one of the optical patterns OPa, OPb, and OPc described with reference to FIG. 11A to FIG. 11C.

Referring to FIG. 16, the positions of the plurality of dicing lines are determined S21 using the frame identifiers. The plurality of dicing lines may be dicing lines for the blade sawing or the laser grooving.

Determining the positions S21 of the plurality of dicing lines is described with reference to the flowchart of FIG. 17. In FIG. 17, visible light is irradiated S211 on a substrate from above the substrate, and an image of the visible light reflected from the substrate is obtained to identify the frame identifier of the unit frame. In an embodiment, when a visible light inspection device 1020 irradiates visible light from above the substrate 12, as described with reference to FIG. 11A to FIG. 11C, the visible light reflected by the integrated circuit structure 11 of the semiconductor wafer 10 forms an image detected by the visible light inspection device 1020. The frame identifier FV is identified using the image reflected in response to visible light.

Based on the identified frame identifier, the positions of the plurality of first dicing lines arranged along a first direction within the unit frame and the positions of the plurality of second dicing lines arranged along a second direction substantially perpendicular to the first direction are identified and determined S212. In an embodiment, referring to FIG. 5, during blade sawing or laser grooving, the positions of the dicing lines X1, X2, X3, X4, and X5 arranged along the first direction and the dicing lines Y1, Y2, and Y3 arranged along the second direction are separately determined based on the size of the chip region CR and the frame identifiers FA1 and FB1 on the semiconductor wafer 10.

Referring to FIG. 16, the process conditions of preliminary dicing are determined S31 for at least one position of the plurality of dicing lines. Preliminary dicing may include, for example, blade sawing or laser grooving. Determining the process conditions of preliminary dicing S31 is described with reference to the flowchart of FIG. 18. The dicing line on which preliminary dicing is performed is selected S311 from among the plurality of dicing lines arranged along the first direction and second direction. The process conditions of preliminary dicing are determined S312 for the selected dicing lines. Referring back to FIG. 5, among the dicing lines X1, X2, X3, X4, and X5 arranged along the first direction and the dicing lines Y1, Y2, and Y3 arranged along the second direction, the dicing line on which the wafer is likely to be un-divided is selected as the dicing line on which preliminary dicing is performed.

Referring to FIG. 16, based on the determined process conditions, preliminary dicing S41 is performed along the plurality of dicing lines for the semiconductor wafer. In an embodiment, preliminary dicing may be performed in the same manner as stealth dicing described with reference to FIG. 15 to cross the plurality of unit frames along the first direction or the second direction with respect to the selected dicing lines.

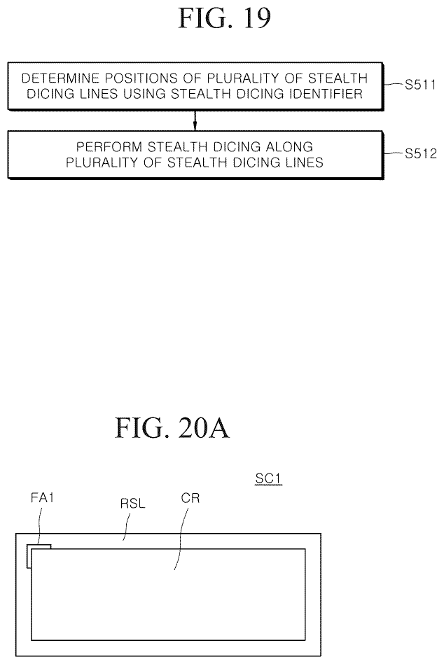

Main dicing S51 is performed on the semiconductor wafer. Main dicing may be, for example, stealth dicing. Main dicing S51 is described with reference to the flowchart of FIG. 19. The positions of the plurality of stealth dicing lines are determined S511 using stealth dicing identifiers separately disposed on the semiconductor wafer. Determining S511 positions of the plurality of stealth dicing lines may be substantially similar to determining the positions of the first and second stealth dicing lines X0 and Y0 using the alignment marks CM of the example described with reference to FIG. 4. The stealth dicing identifiers may be substantially similar to the alignment mark CM disposed within the chip region CR. In an embodiment, determining S511 positions of the plurality of stealth dicing lines is performed without the process of identifying the unit frame within the semiconductor wafer 10.

Stealth dicing S512 is performed along the plurality of stealth dicing lines. Stealth dicing may be performed under the same process conditions for the each of the plurality of stealth dicing lines. In an embodiment, stealth dicing performed on the first stealth dicing lines X0 arranged along the first direction may utilize the same process conditions. Similarly, stealth dicing performed on the second stealth dicing lines Y0 arranged along the second direction may utilize the same process condition.

As described, according to an embodiment of the present disclosure, before main dicing is performed, preliminary dicing is performed on the dicing lines where non-division may occur. During preliminary dicing, a plurality of dicing lines within a unit frame are identified using frame identifiers, thereby selecting dicing lines on which to perform preliminary dicing. After preliminary dicing, main dicing, or stealth dicing, is performed along separately determined stealth dicing lines. The occurrence of defects due to non-division may be effectively prevented in at least some regions of the wafer or the occurrence of unwanted bending due to excessive division when dicing a semiconductor wafer in accordance with the present disclosure.

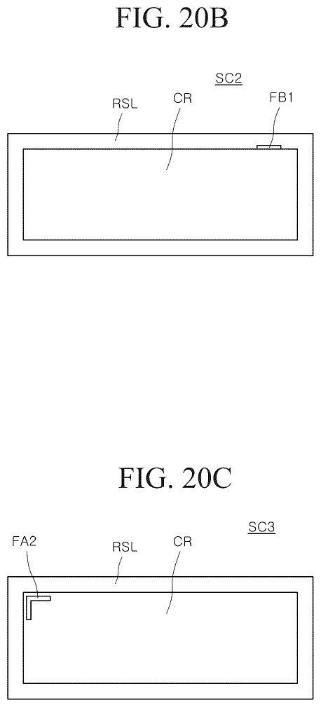

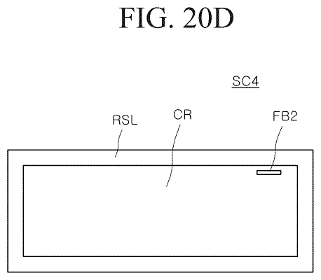

FIG. 20A to FIG. 20D are views illustrating semiconductor chips according to an embodiment of the present disclosure. First semiconductor chip SC1, second semiconductor chip SC2, third semiconductor chip SC3, and fourth semiconductor chip SC4 of FIG. 20A, FIG. 20B, FIG. 20C, and FIG. 20D, respectively, are manufactured by the method of processing a semiconductor wafer described with reference to FIG. 12 to FIG. 14 or the method of processing a semiconductor wafer described with reference to FIG. 16 to FIG. 19.

The first semiconductor chip SC1 of FIG. 20A and the second semiconductor chip SC2 of FIG. 20B are obtained from the chip region CR and the scribe lane SL disposed in the unit frame UF1 of FIG. 5. The third semiconductor chip SC3 of FIG. 20C and the fourth semiconductor chip of FIG. 20D are obtained from the chip region CR and the scribe lane SL disposed in the unit frame UF2 of FIG. 9. As described with reference to FIG. 5 and FIG. 9, because the frame identifiers FA1, FA2, FB1, and FB2 are spaced apart from the plurality of dicing lines X1, X2, X3, X4, X5, Y1, Y2, and Y3, after dicing the semiconductor wafer 10, the frame identifiers FA1, FA2, FB1, and FB2 may remain in the semiconductor chips SC1, SC2, SC3, and SC4, respectively.

In an embodiment, the semiconductor chips SC1, SC2, SC3, and SC4 have a substrate 12 including a chip region CR and a residual scribe lane RSL located outside the chip region CR. The residual scribe lane RSL refers to an area of the scribe lane SL remaining in the semiconductor chips SC1, SC2, SC3, and SC4 after the semiconductor wafer is diced along the plurality of dicing lines X1, X2, X3, X4, X5, Y1, Y2, and Y3 to manufacture the semiconductor chips SC1, SC2, SC3, and SC4.

In an embodiment, at least one of the semiconductor chips SC1, SC2, SC3, and SC4 includes an infrared pattern, identified by infrared rays that are incident to a lower surface of the substrate 12, as frame identifiers FA1, FA2, FB1, and FB2, respectively disposed on an upper surface of the substrate 12. In this example, the frame identifiers FA1, FA2, FB1, and FB2 are infrared markers. In another embodiment, at least one of the semiconductor chips SC1, SC2, SC3, and SC4 includes a visible light pattern, identified by visible light incident from above the substrate 12, as the frame identifiers FA1, FA2, FB1, and FB2, respectively. In this example, the frame identifiers FA1, FA2, FB1, and FB2 are visible light markers.

The infrared markers and the visible light markers include a plurality of optical patterns including integrated circuit structures having different stack structures. The plurality of optical patterns generate differences in brightness through different light reflection and light transmission characteristics resulting from the different stack structures of the integrated circuit structures. The infrared marker and/or the visible light marker may include a check or grid pattern formed by the plurality of optical patterns.

In an embodiment, as described with reference to FIG. 10A to FIG. 10C, the infrared markers include a plurality of optical patterns OP1, OP2, and OP3 that generate differences in brightness due to the material properties of material layers G and arrangement of P1, P2, and P3 at different distances from the upper surface of the substrate 12. In another embodiment, as described with reference to FIG. 11A to FIG. 11C, visible light markers include a plurality of optical patterns OPa, OPb, and OPc that generate differences in brightness depending on the structure of interconnection lines and interlayer insulating layers of the substrate 12.

The plurality of optical patterns OP1, OP2, OP3, OPa, OPb, and OPc are arranged at a corner of the chip region CR adjacent to the scribe lane SL as in FIG. 20A or at a corner located inside the chip region CR as in FIG. 20C. The plurality of optical patterns OP1, OP2, OP3, OPa, OPb, and OPc are arranged along the second direction (length) and first direction (height) of the chip region CR. The detailed arrangement method of the plurality of optical patterns OP1, OP2, OP3, OPa, OPb, and OPc may be substantially similar to the arrangement of FIG. 6.

The plurality of optical patterns OP1, OP2, OP3, OPa, OPb, and OPc are disposed in the scribe lane SL as shown in FIG. 20B or located in the chip region CR as shown in FIG. 20D. The plurality of optical patterns OP1, OP2, OP3, OPa, OPb, and OPc are arranged in one direction along the second direction (length) or the first direction (height) of the chip region CR. The detailed arrangement of the plurality of optical patterns OP1, OP2, OP3, OPa, OPb, and OPc may be substantially similar to the arrangement of FIG. 7.

When the plurality of optical patterns OP1, OP2, OP3, OPa, OPb, and OPc are arranged in the chip region CR, the plurality of optical patterns OP1, OP2, OP3, OPa, OPb, and OPc may be arranged in a peripheral circuit arrangement area among a cell arrangement area and the peripheral circuit arrangement area of the chip region CR.

A semiconductor chip according to an embodiment may include a substrate including a plurality of chip regions and a scribe lane located between the chip regions and an optical marker disposed in conjunction with a first chip region of the plurality of chip regions. The optical marker may include a plurality of optical patterns disposed on the substrate and arranged to identify positions of a plurality of dicing lines for separating the plurality of chip regions. A first optical pattern of the plurality of optical patterns may include a first integrated circuit structure having a first stack structure and a second integrated circuit structure having a second stack structure. The first optical pattern may be associated with a first light reflection characteristic, and a second optical pattern of the plurality of optical patterns may be associated with a second light reflection characteristic.

Although the detailed embodiments of the present disclosure are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor chip comprising:
a substrate including a chip region and a residual scribe lane surrounding the chip region; and
an infrared marker disposed inside the chip region or in the residual scribe lane, the infrared marker including a plurality of optical patterns;
wherein the plurality of optical patterns includes integrated circuit structures with different stack structures over the substrate, and the plurality of optical patterns have differing infrared reflection characteristics.

2. The semiconductor chip of claim 1, wherein the plurality of optical patterns are arranged in the residual scribe lane near an edge of the chip region along a first direction and a second direction of the chip region.

3. The semiconductor chip of claim 1, wherein the plurality of optical patterns are arranged in the residual scribe lane in a direction along one of a first direction and a second direction of the chip region.

4. The semiconductor chip of claim 1,
wherein the chip region includes a cell arrangement area and a peripheral circuit arrangement area, and
wherein the infrared mark is disposed in the peripheral circuit arrangement area.

5. The semiconductor chip of claim 1, wherein the plurality of optical patterns are arranged at a corner located inside the chip region.

6. The semiconductor chip of claim 1, wherein the plurality of optical patterns are arranged in the chip region along one of a first direction and a second direction of the chip region.

7. The semiconductor chip of claim 1, wherein the plurality of optical patterns of the infrared marker form a check pattern associated with a difference in brightness among the plurality of optical patterns.

8. A semiconductor wafer comprising:
a unit frame repeatedly arranged on a substrate, wherein the unit frame includes:
a plurality of chip regions;
a scribe lane disposed between the plurality of chip regions; and
a frame identifier disposed in at least one of the plurality of chip regions or in the scribe lane and providing reference that identify positions of a plurality of dicing lines.

9. The semiconductor wafer of claim 8, wherein the frame identifier is a single identifier dispose within the unit frame.

10. The semiconductor wafer of claim 8,
wherein at least one of the plurality of chip regions includes a cell arrangement area and a peripheral circuit arrangement area, and
wherein the frame identifier is arranged in the peripheral circuit arrangement area.

11. The semiconductor wafer of claim 8,
wherein the frame identifier includes a plurality of optical patterns including integrated circuit structures with different stack structures, and
wherein the plurality of optical patterns are identified through light reflection and light transmission characteristics of the integrated circuit structures.

12. The semiconductor wafer of claim 11, wherein each of the plurality of optical patterns is associated with a different one of a plurality of images that are formed by infrared rays irradiated on a first surface of the substrate.

13. The semiconductor wafer of claim 11, wherein each of the plurality of optical patterns is associated with a different one of a plurality of images that are formed by visible light irradiated on the substrate.
